(19) United States
(12) Patent Application Publication
(10) Pub. No.: US 2017/0067162 A1
(43) Pub. Date: Mar. 9, 2017

(54) WAFER HOLDER AND SEMICONDUCTOR MANUFACTURING APPARATUS

(71) Applicant: Kabushiki Kaisha Toshiba, Tokyo (JP)

(72) Inventors: Takuya Matsuda, Yokohama Kanagawa (JP); Kazunari Yabe, Kanazawa Ishikawa (JP); Takahiro Terada, Yokohama Kanagawa (JP); Noriyuki Moriya, Yokohama Kanagawa (JP); Hidenori Hanyu, Kanazawa Ishikawa (JP)

(73) Assignees: Kabushiki Kaisha Toshiba, Minato-ku, Tokyo (JP); Kabushiki Kaisha Toshiba, Minato-ku, Tokyo (JP)

(21) Appl. No.: 15/017,880

(22) Filed: Feb. 8, 2016

(30) Foreign Application Priority Data
Sep. 9, 2015 (JP) 2015-177689

(51) Int. Cl. C23C 16/46; C23C 16/458; C23C 16/455; H01L 21/687; H01L 21/67

(52) U.S. Cl. CPC C23C 16/46; H01L 21/68785; H01L 21/68771; H01L 21/67098; C23C 16/455; C23C 16/458

(57) ABSTRACT

A wafer holder according to an embodiment includes a wafer holder. A wafer support-portion is provided at an end portion of a mount region for a wafer. A first portion is located nearer a central portion of the mount region than the wafer support-portion. A first depth of the first portion with reference to an upper surface of the wafer holder outside the mount region is larger than a second depth of the wafer support-portion and a third depth of a third portion located nearer the central portion of the mount region than the first portion. A second portion is located nearer the central portion of the mount region than the wafer support-portion. A fourth depth of the second portion with reference to the upper surface of the wafer holder outside the mount region is larger than the second and third depths and smaller than the first depth.

### CROSS REFERENCE TO RELATED APPLICATIONS

This application is based upon and claims the benefit of priority from the prior Japanese Patent Application No. 2015-177689, filed on Sep. 9, 2015, the entire contents of which are incorporated herein by reference.

### FIELD

The embodiments of the present invention relate to a wafer holder and a semiconductor manufacturing apparatus.

### BACKGROUND

In a film forming apparatus such as an MOCVD (Metal Organic Chemical Vapor Deposition) apparatus, when a semiconductor wafer is processed, the semiconductor wafer is mounted on a wafer holder and a process gas is supplied onto the semiconductor wafer while the wafer holder is heated and rotated. This configuration enables a desired material film to be formed on the semiconductor wafer. If variation in temperature distribution on the semiconductor wafer is large in this film forming process, the film thickness and the like of the formed material film vary.

During the film forming process, the temperature of the semiconductor wafer greatly depends on the thermal conductive property of the wafer holder that holds the semiconductor wafer. Therefore, it is desired that the thermal conductive property of the wafer holder to the wafer is as uniform as possible.

### BRIEF DESCRIPTION OF THE DRAWINGS

FIG. 1 is a perspective sectional view showing a film forming apparatus 1 according to a first embodiment;

FIG. 2 is a plan view showing the wafer holder 20 according to the first embodiment;

FIG. 3 is a sectional view schematically showing thermal conduction in one mount region R;

FIG. 4 is a plan view showing a configuration of wafer support portions 26;

FIG. 5 is a plan view showing the positions of the first and second portions 21 and 22 in more detail;

FIG. 6 is a plan view showing the mount region R in which first portions 21_5 correspond to the wafer support portions 26; and

FIGS. 7A and 7B are sectional views showing boundary between the first portion 21 and the second portion 22.

### DETAILED DESCRIPTION

Embodiments will now be explained with reference to the accompanying drawings. The present invention is not limited to the embodiments.

A wafer holder according to an embodiment includes a wafer holder. A wafer support portion is provided at an end portion of a mount region for a wafer. A first portion is located nearer a central portion of the mount region than the wafer support portion. A first depth of the first portion with reference to an upper surface of the wafer holder outside the mount region is larger than a second depth of the wafer support portion and a third depth of a third portion located nearer the central portion of the mount region than the first portion. A second portion is located nearer the central portion of the mount region than the wafer support portion. A fourth depth of the second portion with reference to the upper surface of the wafer holder outside the mount region is larger than the second and third depths and smaller than the first depth.

### First Embodiment

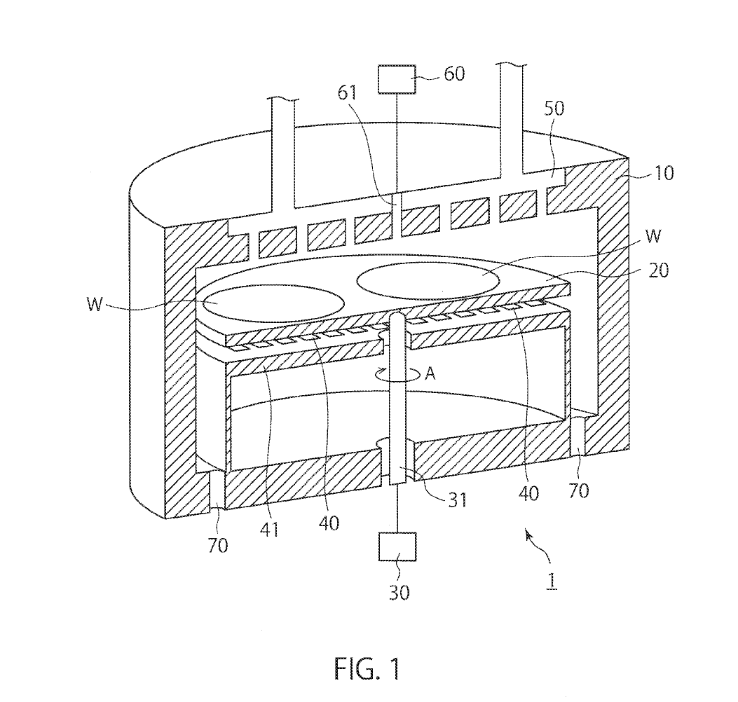

FIG. 1 is a perspective sectional view showing a film forming apparatus 1 according to a first embodiment. The film forming apparatus 1 is, for example, an MOCVD apparatus and includes a reaction chamber 10, a wafer holder (a susceptor) 20, a driver 30, a heater 40, a gas supplier 50, a radiation thermometer 60, and a discharge port 70.

The reaction chamber 10 is used to form a material film on surfaces of semiconductor wafers (hereinafter, also simply “wafers”) W mounted on the wafer holder 20. The inside of the reaction chamber 10 is vacuumed to a depressurized state when wafers W are processed.

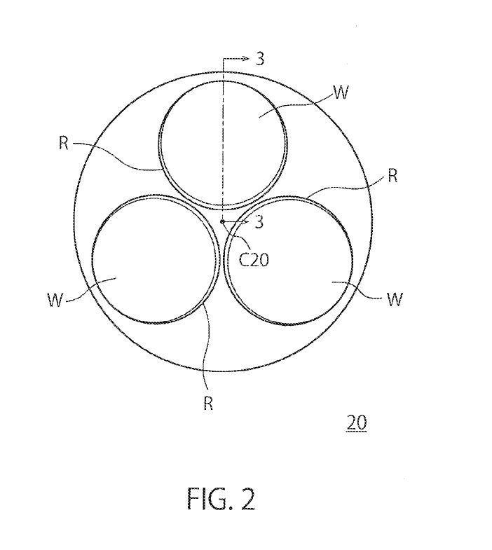

The wafer holder 20 can have wafers W mounted thereon in mount regions (pockets) provided on a top face thereof as a first face. In the first embodiment, the wafer holder 20 can have, for example, three wafers W mounted thereon. However, the number of wafers W that can be mounted on the wafer holder 20 is not particularly limited. The wafer holder 20 is coupled to a shaft 31 at a central portion (C20 in FIG. 2) thereof and can rotate around the shaft 31 (C20) in a substantially horizontal plane. The shaft 31 is connected to the driver 30 and is rotationally driven by the driver 30. The wafer holder 20 receives heat from the heater 40 placed therebelow and heats the wafers W with the heat. The wafer holder 20 is configured to be removable from the reaction chamber 10 and to be replaceable with another wafer holder.

The driver 30 can rotate the wafer holder 20 in the direction of an arrow A or in the opposite direction thereof via the shaft 31.

The heater 40 is placed below the wafer holder 20 and is arranged substantially concentrically around the shaft 31 (the center of the wafer holder 20). A thermal insulator 41, a reflector, or the like is provided below the heater 40.

The gas supplier 50 is provided at an upper portion of the reaction chamber 10 and supplies a source gas from a gas supply source (not shown) onto the wafers W.

The radiation thermometer 60 is placed at a window 61 provided at the upper portion of the reaction chamber 10 and measures the temperatures of the wafers W through the window 61.

The film forming apparatus 1 described above heats and rotates the wafers W together with the wafer holder 20 and supplies a source gas serving as a source of a compound semiconductor crystal onto the top faces of the wafers W, thereby epitaxially growing a compound semiconductor layer on the top faces of the wafers W. The source gas is discharged from the discharge port 70 after being used in film formation.

For example, in a case where a group-III nitride semiconductor layer is formed as an example of the compound semiconductor layer, organic metal containing a group-III element and ammonia (NH₃) containing nitrogen are used as the source gas. Examples of the organic metal include trimethylgallium (TMG) or triethylgallium (TEG) containing Ga(III), trimethylaluminium (TMA) or triethylaluminum (TEA) containing Al(III), and trimethylindium (TMI) or triethylindium (TEI) containing In(III). As an n-type dopant, a monosilane (SiH₄) or disilane (Si₂H₆) can be used as a Si source, or a germane gas (GeH₄), tetramethylgermanium ((CH₃)₄Ge), or tetraethylgermanium ((C₂H₅)₄Ge) can be used as a Ge source. As a p-type dopant, bis cyclopentadienyl magnesium (Cp₂Mg) or his ethylcyclopentadienyl magnesium (EtCp₂Mg) can be used as an Mg source, for example. Furthermore, hydrazine (N₂H₄) can be used instead of ammonia. In addition to the organic metal gases described above, a gas containing another group-III element can be used and a dopant such as Ge, Si, Mg, Ca, Zn, or Be can be contained as required.

FIG. 2 is a plan view showing the wafer holder 20 according to the first embodiment. The wafer holder 20 has, for example, three mount regions R to enable three wafers W to be mounted thereon. The three mount regions R are arranged on a front face as the first face substantially evenly at positions away from the central portion C20 of the wafer holder 20 by substantially equal distances, respectively. The mount regions R are of a substantially circular shape having a slightly larger diameter than that of the wafers W and are recessed to receive the wafers W when having the wafers W mounted thereon, respectively. The planar shape of the mount regions R is not particularly limited thereto as long as it is a shape (a similar figure, for example) adapted to the wafers W.

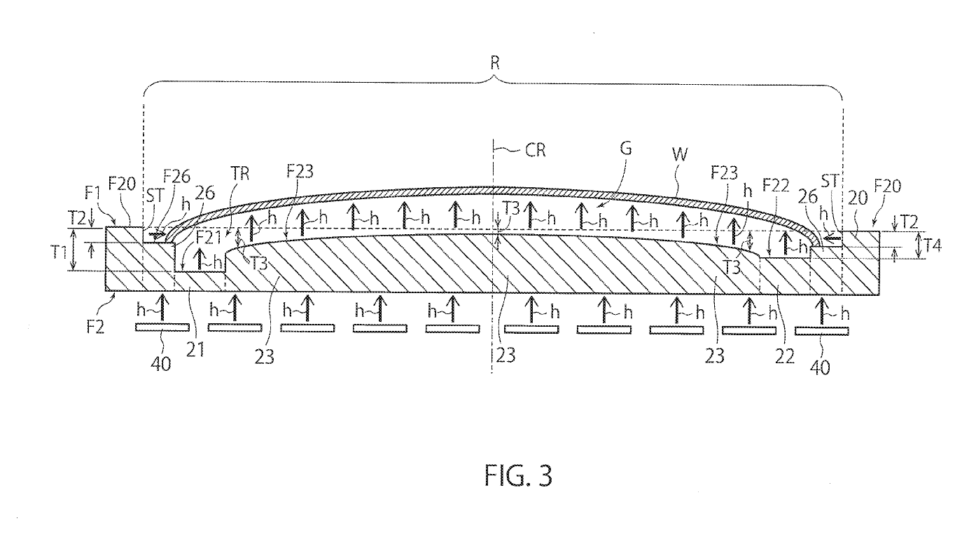

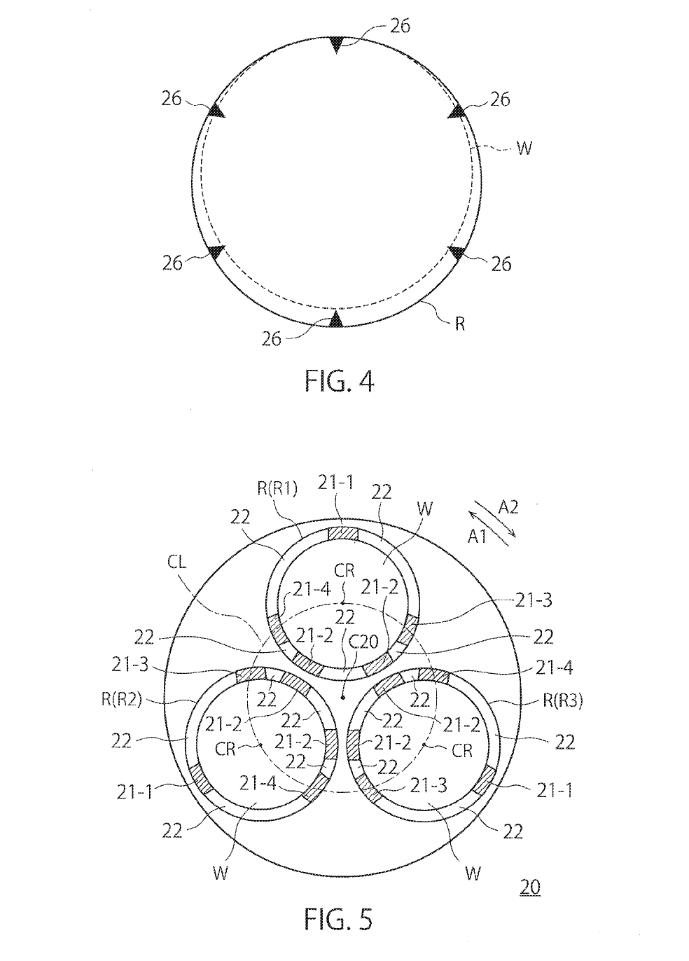

FIG. 3 is a sectional view schematically showing thermal conduction in one mount region R. FIG. 3 corresponds to a cross-section along a line 3-3 in FIG. 2. FIG. 4 is a plan view showing a configuration of wafer support portions 26. A structure of the mount region R of the wafer holder 20 is explained in more detail below with reference to FIGS. 3 and 4.

The wafer holder 20 has a first face F1 and a second face F2 on the opposite side to the first face F1. The first face F1 is a top face on which the wafer W can be mounted and is provided with the mount region R for the wafer W. The second face F2 is a rear face that receives heat from the heater 40. The heat from the heater 40 is transmitted through the wafer holder 20 from the second face F2 of the wafer holder 20 to the first face F1 thereof and is transmitted to the wafer W mounted on the mount region R in the first face F1 as shown by arrows. There is a gap G between the mount region R and the wafer W and heat from the first face F1 is transmitted to the wafer W via the gap G. Thermal conduction from the wafer holder 20 to the wafer W is explained in detail later.

The wafer holder 20 includes the wafer support portions 26, first portions 21, second portions 22, and a third portion 23 in the mount region R.

The wafer support portions 26 are provided at an end portion of the mount region R and are brought into contact with an end portion of the wafer W to support the wafer W when the wafer W is mounted. A top face F26 of each of the wafer support portions 26 is slightly recessed with respect to a part of the first face F1 outside the mount region R and a step ST is provided at an outer edge of the mount region R. Accordingly, even when the wafer W moves in a direction substantially parallel to the first face F1 or the top face F26 when the wafer holder 20 rotates, the end portion of the wafer W hits a side face of the step ST. Therefore, the wafer W does not protrude from the mount region R and is kept within the mount region R.

The wafer support portions 26 are provided at parts of the outer edge of the mount region R. For example, in the plan view showing the mount region R in FIG. 4, the wafer support portions 26 are provided at six positions on the outer edge of the mount region R and the wafer W can be supported by the six support portions 26. The wafer support portions 26 are arranged to be capable of supporting the wafer W even when the wafer W is moved toward one side of the mount region R as indicated by a dashed line. Needless to mention, the number and the size of the wafer support portions 26 are not particularly limited.

Referring back to FIG. 3, the first portions 21 are provided near the outer edge of the mount region R similarly to the wafer support portions 26. At the positions where the wafer support portions 26 are provided, the first portions 21 are provided on a side nearer a central portion CR of the mount region R than the wafer support portions 26 and are interposed between the wafer support portions 26 and the third portion 23 that is located on a side nearer the central portion CR of the mount region R than the first portions 21, respectively.

The first portions 21 are not provided on the entire outer circumference of the mount region R but are provided locally to correspond to parts of the outer circumference of the mount region R to face parts of the outer edge of the wafer W, respectively. Positions where the first portions 21 are provided are explained later with reference to a plan view of FIG. 5.

With reference to a front face F20 of the wafer holder 20 outside the mount region R, a first depth T1 of the first portions 21 is larger than a second depth 12 of the wafer support portions 26. Further, the first depth T1 is larger than a third depth T3 of the wafer holder 20 in the third portion 23. Accordingly, the front faces F21 of the first portions 21 are recessed toward the rear face F2 with respect to the front faces F26 of the wafer support portions 26 and a front face F23 of the third portion 23 and form trenches TR, respectively. The trenches TR are provided at the end portion of the mount region R and are provided to face the end portion of the wafer W mounted in the mount region R. The function of the trenches TR is described later.

The second portions 22 are provided near the outer edge of the mount region R similarly to the first portions 21. At the positions where the wafer support portions 26 are provided, the second portions 22 are provided on a side nearer the central portion CR of the mount region R than the wafer support portions 26 and are interposed between the wafer support portions 26 and the third portion 23, respectively. The second portions 22 are not provided on the entire outer circumference of the mount region R but are provided locally to correspond to other parts of the outer circumference of the mount region R to face other parts of the outer edge of the wafer W, respectively. That is, the second portions 22 are provided at positions of the end portion of the mount region R other than the positions where the first portions 21 are provided. The positions where the second portions 22 are provided are explained later with reference to the plan view of FIG. 5.

With reference to the front face F20 of the wafer holder 20 outside the mount region R, a fourth depth T4 of the second portions 22 is equal to or larger than the second depth T2 of the wafer support portions 26 and the third depth T3 of the third portion 23. Further, the fourth depth T4 is smaller than the first depth T1 of the first portions 21. Accordingly, the front faces F22 of the second portions 22 can be recessed toward the rear face F2 with respect to the front face F26 of the wafer support portions 26 and the front face F23 of the third portion 23 respectively, or can be substantially flush with the front face F26 or F23. Therefore, the front faces F22 of the second portions 22 can form trenches or do not need to form trenches. When there are trenches in the second portions 22, the trenches are shallower than the trenches TR of the first portions 21 because the fourth depth T4 is smaller than the first depth T1 of the first portions 21. That is, while provided to face the end portion of the wafer W similarly to the first portions 21, the second portions 22 do not always form trenches.

The third portion 23 is provided nearer the central portion CR of the mount region R than the wafer support portions 26 and the first and second portions 21 and 22 and has a convex shape protruding at the central portion CR of the mount region R. That is, the front face F23 of the third portion 23 has a convex shape to become closer to the second face F2 as approaching from the central portion CR of the mount region R to the outer edge of the mount region R. For example, when an n-type AlGaN single crystalline layer (not shown) is epitaxially grown in the film forming apparatus 1, the wafer W is distorted due to a difference in the lattice constant between a sapphire substrate and the N-type AlGaN single crystalline layer. Accordingly, the wafer W warps in a convex shape as shown in FIG. 3. The third portion 23 is formed in a convex shape to correspond to the convex shape caused by warp of the wafer W. That is, the convex shape of the third portion 23 is formed to be adapted to the convex shape of the wafer W when a layer (an n-type AlGaN single crystalline layer, for example) having the largest effect on characteristics of a semiconductor device is formed. In a plan view as viewed from above the wafer holder 20, the apex (the central portion CR) of the convex shape of the third portion 23 is substantially matched with the apex of the convex shape of the wafer W. Accordingly, the distance (the interval of the gap G) between the front face F23 of the third portion 23 and the wafer W becomes substantially uniform in the third portion 23 in the mount region R. As a result, heat can be transmitted to the wafer W substantially uniformly in the third portion 23 of the wafer holder 20. When the wafer W warps in a concave shape, the third portion 23 can be formed in a concave shape to correspond thereto. In FIG. 3, boundaries between the third portion 23 and the first portions 21 have steps in a direction substantially perpendicular to the front face F21, respectively. However, at the boundaries between the third portion 23 and the first portions 21 and boundaries between the third portion 23 and the second portions 22, the third portion 23 can connect to the first portions 21 or the second portions 22 with a gradual inclination.

Thermal conduction from the wafer holder 20 to the wafer W is explained next.

As described above, heat can be transmitted substantially uniformly to the wafer W in the third portion 23. On the other hand, at the end portion of the mount region R, heat is conducted to the wafer W also from the wafer support portions 26 or the steps ST with which the wafer W is in direct contact as shown by arrows h in FIG. 3. Accordingly, the temperature of the end portion of the wafer W during film formation tends to be higher than the temperature of a central portion of the wafer W (a region of the wafer W corresponding to the third portion 23). Furthermore, heat transmitted to the wafer W is likely to vary also depending on the position of the wafer W on the wafer holder 20 or in the mount region R.

The wafer holder 20 according to the first embodiment thus has the first portions 21 and the second portions 22 at the end portion of the mount region R, which are different in depths (thicknesses) of the wafer holder 20. The trenches TR are provided at parts of the end portion of the mount regions R in which the first portions 21 are provided. Therefore, the front faces F21 of the first portions 21 are relatively distant from the end portion of the wafer W mounted in the mount region R. That is, the distance between the wafer holder 20 and the end portion of the wafer W is larger in the first portions 21. Accordingly, heat from the wafer holder 20 becomes less easily to be transmitted to the wafer W (thermal resistance is increased), which relatively decreases the temperature of parts of the end portion of the wafer W facing the first portions 21. On the other hand, the trenches TR are not provided at parts of the end portion of the mount region R in which the second portions 22 are provided. Even in a case where trenches are provided, the trenches are shallower than the trenches TR in the first portions 21. Therefore, the front faces F22 of the second portions 22 are relatively near to the end portion of the wafer W mounted in the mount region R. That is, the distance between the wafer holder 20 and the end portion of the wafer W is smaller in the second portions 22. Accordingly, heat from the wafer holder 20 becomes easier to be transmitted to the wafer W (thermal resistance is decreased) and the temperature of parts of the end portion of the wafer W facing the second portions 22 becomes relatively high.

In this manner, according to the first embodiment, with changes in the distance between the wafer W and the front face (F21 or F22) of the wafer holder 20 at the end portion of the mount region R, thermal conductivities (thermal conductances) of the first and second portions 21 and 22 of the wafer holder 20 are adjusted, and consequently variation in temperature distribution on the wafer W can be suppressed. The depth, the width, and the length of the trenches TR of the first portions 21 are not particularly limited and can be appropriately set according to the state of variation in the temperature distribution on the wafer W.

FIG. 5 is a plan view showing the positions of the first and second portions 21 and 22 in more detail. In FIG. 5, the first portions 21 are denoted by reference numerals 21_1 to 21_4. Parts of the end portion of the mount region R other than the first portions 21 are the second portions 22, respectively. FIG. 5 is a plan view showing the wafer holder 20 that does not have the wafers W mounted thereon. For convenience sake, illustrations of the wafer support portions 26 are omitted in FIG. 5.

As described above, during a film forming process, the temperature of the parts of the end portion of a wafer W corresponding to (facing) the first portions 21 becomes relatively low and the temperature of the parts of the end portion of the wafer W corresponding to (facing) the second portions 22 becomes relatively high. In the first embodiment, the positions of the first and second portions 21 and 22 are set utilizing these characteristics to suppress variation in temperature distribution at the end portion of the wafer W.

### (Positions of First Portions 21 Considering Centrifugal Force)

During a film forming process, the wafer holder 20 rotates in the direction of an arrow A1 or A2 around the central portion C20. At that time, the centrifugal force is applied to the wafer W and the wafer W moves in the radial direction from the central portion C20 of the wafer holder 20 within the range of the mount region R. Therefore, the wafer W is brought into contact with the step ST the farthest from the central portion C20 of the wafer holder 20 in the mount region R. Because it is considered that the temperature is increased at a part of the end portion of the wafer W in contact with the step ST in this case, the first portion 21_1 is provided at the farthest portion from the central portion C20 of the wafer holder 20 in the mount region R. Accordingly, temperature differences in the wafer W between the first portion 21_1 and the second portions 22 are reduced and variation in temperature distribution at the end portion of the wafer W can be suppressed.

### (Positions of First Portions 21 Considering Adjacent Mount Regions R)

The mount region R has a substantially circular shape to be adapted to the planar shape of the wafer W. Accordingly, when the wafer holder 20 has a plurality of the mount regions R, there are portions where adjacent mount regions R are the closest to each other. During a film forming process, heat is likely to be accumulated in the mount regions R covered by the wafers W in the wafer holder 20 and is likely to diffuse in a region where the wafers W are not present (that is, a region other than the mount regions R). Therefore, it is considered that the temperature of the wafers W become relatively high in the portions where adjacent mount regions R are the closest to each other.

In the first embodiment, in a case where the wafer holder 20 has first to third mount regions R1 to R3 as shown in FIG. 5, the first portions 21_2 are provided at portions where the first to third mount regions R1 to R3 are adjacent to each other, respectively. That is, the first portions 21_2 in the first mount region R1 are provided at portions the closest to the second mount region R2 and the third mount region R3 in the first mount region R1, respectively. Similarly, the first portions 21_2 in the second mount region R2 are provided at portions the closest to the first mount region R1 and the third mount region R3 in the second mount region R2, respectively. Still similarly, the first portions 21_2 in the third mount region R3 are provided at portions the closest to the first mount region R1 and the second mount region R2 in the third mount region R3, respectively. This configuration can reduce temperature differences in the wafers W between the first portions 21_2 and the second portions 22 and can suppress variation in temperature distribution at the end portions of the wafers W.

### (Positions of First Portions 21 Considering Increase or Decrease in Rotation Speed of Wafer Holder 20)

In some cases, the wafer holder 20 changes the rotation speed during a film forming process. For example, in a case where a plurality of material films are consecutively formed, the driver 30 sometimes changes the rotation speed of the wafer holder 20 when a first material film is formed and then a second material film is formed. In such a case, acceleration is applied to the wafers W placed in the mount regions R and the wafers W move in the rotation direction A1 or A2 around the central portion C20 of the wafer holder 20 within the range of the mount regions R. That is, each of the wafers W is brought into contact with the steps ST that are provided at two end portions in each of the mount regions R intersecting with a circle CL that passes through the central portion CR of the mount region R around the central portion C20 of the wafer holder 20. Because it is considered that the temperature increases at the end portions of each of the wafers W being in contact with the steps ST, the first portions 21_3 and 21_4 are provided at the two end portions in each of the mount regions R intersecting with the circle CL, respectively. Temperature differences in the wafers W between the first portions 21_3 and 21_4 and the second portions 22 can thus be reduced and variation in temperature distribution at the end portions of the wafers W can be suppressed.

Either the first portion 21_3 or 21_4 can be provided in the mount region R. For example, in a case where variation in the temperature distribution at the end portion of the wafer W is to be suppressed when the wafer holder 20 is accelerated in the direction A1, the first portion 21_3 can be provided and the first portion 21_4 can be omitted. This configuration can suppress variation in the temperature distribution at the end portion of the wafer W when the wafer holder 20 is accelerated in the direction A1. Meanwhile, in a case where variation in the temperature distribution at the end portion of the wafer W is to be suppressed when the wafer holder 20 is accelerated in the direction A2, the first portion 21_4 can be provided and the first portion 21_3 can be omitted. This configuration can suppress variation in the temperature distribution at the end portion of the wafer W when the wafer holder 20 is accelerated in the direction A2.

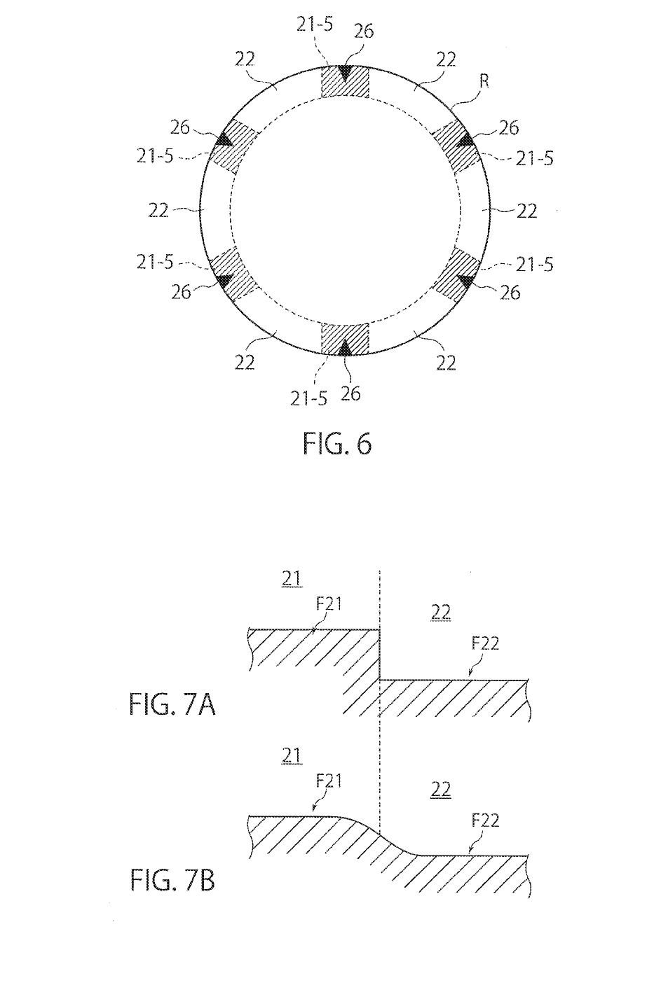

Furthermore, the first portions 21 can be provided to correspond to the wafer support portions 26. For example, FIG. 6 is a plan view showing the mount region R in which first portions 21_5 correspond to the wafer support portions 26, respectively. In FIG. 6, the first portions 21 are parts denoted by 21_5 in the end portion of the mount region R. Other parts of the end portion in the mount region R are the second portions 22. In this case, FIG. 6 is a plan view showing the mount region R on which the wafer W is not mounted.

As explained with reference to FIG. 3, the temperature of the wafer W is high in portions being in contact with the wafer holder 20. Therefore, it is considered that temperatures of parts of the end portion of the wafer W being in contact with the wafer support portions 26 are likely to be high. Therefore, the first portions 21_5 can be provided at parts where the wafer support portions 26 are provided in the end portion of the mount region R. Temperature differences in the wafer W between the first portions 21_5 and the second portions 22 can thus be reduced and variation in temperature distribution at the end portion of the wafer W can be suppressed.

The first portions 21_1 to 21_S described above can all be provided on the wafer holder 20. Alternatively, any one or more of the first portions 21_1 to 21_5 can be provided on the wafer holder 20. However, if the first portions 21 are provided on the entire end portion of the mount region R, variation in the temperature distribution at the end portion of the mount region R cannot be suppressed. Therefore, the first portions 21 are provided locally at parts of the end portion of the mount region R and the second portions 22 are provided at remaining parts of the end portion of the mount region R. The depths (T1) of the first portions 21_1 to 21_5 can be equal to or different from each other. The depths (T4) of the second portions 22 can be also equal to or different from each other.

At the end portion of the mount region R, boundaries between the first portions 21 and the second portions 22 can be steps or can be inclined smoothly. For example, FIGS. 7A and 7B are sectional views of the wafer holder 20 showing a boundary between the first portion 21 and the second portion 22. In FIG. 7A, the boundary between the first portion 21 and the second portion 22 is a step. While the boundary between the first portion 21 and the second portion 22 is clearly defined in this case, heat transfer characteristics change greatly at the boundary.

On the other hand, in FIG. 7B, the boundary between the first portion 21 and the second portion 22 is inclined smoothly. That is, the boundary between the first portion 21 and the second portion 22 is inclined with respect to the front face F21 of the first portion 21, the front face F22 of the second portion 22, or the first face F1 (see FIG. 3). Accordingly, the first portion 21 and the second portion 22 are connected smoothly and heat transfer characteristics gradually change. Therefore, inclination of the boundary leads to further suppression of variation in the temperature distribution on the wafer W. As described above, the wafer holder 20 according to the first embodiment has the first portions 21 and the second portions 22. The relatively deep trenches TR are provided in the first portions 21 at the end portion of the mount region R. The trenches TR are not provided in the second portions 22 or relatively shallow trenches are provided therein. The positions of the first and second portions 21 and 22 are appropriately set at the end portion of the mount region R. Thermal conductivity (thermal conductance) of the wafer holder 20 is thus adjusted and variation in the temperature distribution on the wafer W during wafer processing can be suppressed.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A wafer holder comprising:
a wafer support portion provided at an end portion of a mount region for a wafer;
a first portion located nearer a central portion of the mount region than the wafer support portion, a first depth of the first portion with reference to an upper surface of the wafer holder outside the mount region being larger than a second depth of the wafer support portion and a third depth of a third portion located nearer the central portion of the mount region than the first portion; and
a second portion located nearer the central portion of the mount region than the wafer support portion, a fourth depth of the second portion with reference to the upper surface of the wafer holder outside the mount region being larger than the second and third depths and smaller than the first depth.

2. The wafer holder of claim 1, wherein the first portion is located at a portion farthest in the mount region from the central portion of the wafer holder.

3. The wafer holder of claim 1, wherein
the mount region for the wafer comprises a first mount region and a second mount region adjacent to the first mount region,
the first portion in the first mount region is located nearest to the second mount region among the first mount region, and
the first portion in the second mount region is located at a portion nearest to the first mount region among the second mount region.

4. The wafer holder of claim 2, wherein
the mount region for the wafer comprises a first mount region and a second mount region adjacent to the first mount region,
the first portion in the first mount region is located nearest to the second mount region among the first mount region, and
the first portion in the second mount region is located at a portion nearest to the first mount region among the second mount region.

5. The wafer holder of claim 1, wherein the first portion is located at at least one of two end portions intersecting with a circle that passes through a center of the mount region around a center of the wafer holder in the mount region.

6. The wafer holder of claim 2, wherein the first portion is located at at least one of two end portions intersecting with a circle that passes through a center of the mount region around a center of the wafer holder in the mount region.

7. The wafer holder of claim 3, wherein
the first portion in the first mount region is located at at least one of two end portions intersecting with a circle that passes through a center of the first mount region around a center of the wafer holder in the first mount region, and
the first portion in the second mount region is located at at least one of two end portions intersecting with a circle that passes through a center of the second mount region around the center of the wafer holder in the second mount region.

8. The wafer holder of claim 1, wherein the first portion is located at an end portion of the mount region, the wafer support portion being provided at the end portion.

9. The wafer holder of claim 1, wherein a boundary between the first portion and the second portion is inclined with respect to an upper surface of the first portion, an upper face of the second portion, or a first face on which the wafer can be mounted.

10. The wafer holder of claim 1, wherein an upper surface of the third portion in the mount region has a convex shape to become closer to a second face as approaching from a center of the mount region to an outer edge of the mount region, the second face of the wafer holder being an opposite side of the first face.

11. A semiconductor manufacturing apparatus comprising:
a chamber processing a wafer;
a wafer holder capable of having the wafer mounted thereon;
a driver rotating the wafer holder;
a heater provided below the wafer holder; and
a gas supplier supplying a gas into the chamber, the gas being used in processing of the wafer into the chamber, wherein
the wafer holder comprises:
a wafer support portion provided at an end portion of a mount region for the wafer;
a first portion located nearer a central portion of the mount region than the wafer support portion, a first depth of the first portion with reference to an upper surface of the wafer holder outside the mount region being larger than a second depth of the wafer support portion and a third depth of a third portion located nearer the central portion of the mount region than the first portion; and
a second portion located nearer the central portion of the mount region than the wafer support portion, a fourth depth of the second portion with reference to the upper surface of the wafer holder outside the mount region being larger than the second and third depths and smaller than the first depth.

12. The apparatus of claim 11, wherein the first portion is provided at a portion farthest in the mount region from a central portion of the wafer holder.

13. The apparatus of claim 11, wherein
the mount region for the wafer comprises a first mount region and a second mount region adjacent to the first mount region,
the first portion in the first mount region is located nearest to the second mount region among the first mount region, and
the first portion in the second mount region is located at a portion nearest to the first mount region among the second mount region.

14. The apparatus of claim 11, wherein the first portion is located at at least one of two end portions intersecting with a circle that passes through a center of the mount region around a center of the wafer holder in the mount region.

15. The apparatus of claim 13, wherein
the first portion in the first mount region is located at at least one of two end portions intersecting with a circle that passes through a center of the first mount region around a center of the wafer holder in the first mount region, and
the first portion in the second mount region is located at at least one of two end portions intersecting with a circle that passes through a center of the second mount region around the center of the wafer holder in the second mount region.

16. The apparatus of claim 11, wherein the first portion is located at an end portion of the mount region, the wafer support portion being provided at the end portion.

17. The apparatus of claim 11, wherein a boundary between the first portion and the second portion is inclined with respect to an upper surface of the first portion, an upper face of the second portion, or a first face on which the wafer can be mounted.

18. The apparatus of claim 11, wherein an upper surface of the third portion in the mount region has a convex shape to become closer to a second face as approaching from a center of the mount region to an outer edge of the mount region, the second face of the wafer holder being an opposite side of the first face.
